(19) United States
(12) Patent Application Publication
(10) Pub. No.: US 2011/0238338 A1
(43) Pub. Date: Sep. 29, 2011

(54) MOTOR DRIVING APPARATUS EASILY ANALYZABLE FOR CAUSE OF FAULT

(75) Inventors: Yasusuke IWASHITA, Minamitsuru-gun (JP); Shinichi Horikoshi, Minamitsuru-gun (JP); Takashi Harada, Minamitsuru-gun (JP); Koujirou Sakai, Minamitsuru-gun (JP)

(73) Assignee: FANUC CORPORATION

(21) Appl. No.: 13/029,496

(22) Filed: Feb. 17, 2011

(30) Foreign Application Priority Data
Mar. 24, 2010 (JP) 2010-068386

(51) Int. Cl. G06F 19/00; G01R 31/00

(52) U.S. Cl. 702/58

(57) ABSTRACT

Disclosed is a motor driving apparatus in which provisions are made so as to easily isolate the cause of a fault in the event of the occurrence thereof. The voltage and current in each phase of the AC power being supplied to a converter are detected, and the most recently detected data are stored in a power supply monitoring unit for a predetermined period of time. If an alarm occurs in the converter, inverter, or controller, the data currently held in the power supply monitoring unit are recorded in a recording unit. By displaying the thus recorded data, one can easily identify whether the cause of the alarm is due to the power supply or the motor driving apparatus itself.

### BACKGROUND OF THE INVENTION

1. Field of the Invention

The present invention relates to a motor driving apparatus in which provisions are made so as to easily identify, in the event of the occurrence of a fault, whether the cause of the fault lies in an input power supply or in the apparatus itself.

2. Description of the Related Art

In a motor control apparatus for driving a machine tool, an industrial machine, a robot, or the like, AC power which is input to a converter that converts the AC input power into DC power is usually a balanced three-phase AC power and is converted from AC to DC without any problem during normal operation.

However, there are cases where the voltage of the power supply drops momentarily or the balanced state of the three phases is disrupted because of the operating condition of another apparatus connected to the power supply or because of power being supplied from a power company (i.e., because of an external factor).

When this happens, the controller that issues a command to the converter or inverter or to the motor may detect an internal fault and cause its operation to stop.

In this case, since the stoppage of the operation is not due to a failure occurring in the apparatus itself, but due to a fault occurring in the input power supply, if the apparatus is investigated or replaced after the occurrence of an alarm, it may not be possible to identify the real cause of the fault and it usually takes a long time to isolate the cause of the fault.

Therefore, it is desired to be able to quickly determine whether or not the stoppage of the operation is due to a fault occurring in the power supply.

JP11-338542A describes that a history of alarms occurring in a motor driving apparatus is recorded and is output on request. However, there is no description of the input power supply.

JP2645144B describes that the input voltage is detected and, when the voltage drops below a predetermined value, the operation of both the converter and the inverter is stopped. On the other hand, JP6-30597A describes that when a momentary power interruption is detected, power to the motor is cut off. However, neither document carries a description about identifying whether the cause of the stoppage of the operation lies in the input power supply or in the apparatus itself.

### SUMMARY OF THE INVENTION

Accordingly, it is an object of the present invention to provide a motor driving apparatus in which provisions are made so as to easily isolate the cause of a fault in the event of the occurrence thereof.

According to the present invention, there is provided a motor driving apparatus comprising: a converter converting AC power into DC power; an inverter converting the DC power output from the converter into frequency variable three-phase AC power for supply to a motor; a controller controlling the converter and the inverter; an input power supply detection unit detecting at least one of a current in each phase and voltage in each phase of the AC power; a power supply monitoring unit storing the most recent data detected by the input power supply detection unit for a predetermined period of time; and a recording unit which saves the data from the power supply monitoring unit for output at a later time, when a fault has occurred in at least one of the converter, the inverter, and the controller.

Since the voltage/current data recorded for a predetermined period of time, starting from the time a predetermined time before the occurrence of a fault and ending at the time a predetermined time has elapsed thereafter, is saved for output at a later time, it becomes easy to identify whether the cause of the fault lies in the power supply or in the motor driving apparatus itself.

### BRIEF DESCRIPTION OF THE DRAWINGS

FIG. 1 is a block diagram of a motor driving apparatus 10 according to one embodiment of the present invention;

FIG. 2 is a diagram showing one configuration example of a voltage detecting portion of a power supply monitoring unit 24 in FIG. 1;

FIG. 3 is a diagram showing one configuration example of a current detecting portion of the power supply monitoring unit 24 in FIG. 1;

FIG. 4 is a diagram showing the waveforms of input current and input voltage during normal operation; and

FIG. 5 is a diagram showing the waveforms of input current and input voltage when a fault condition occurs.

### DESCRIPTION OF THE PREFERRED EMBODIMENTS

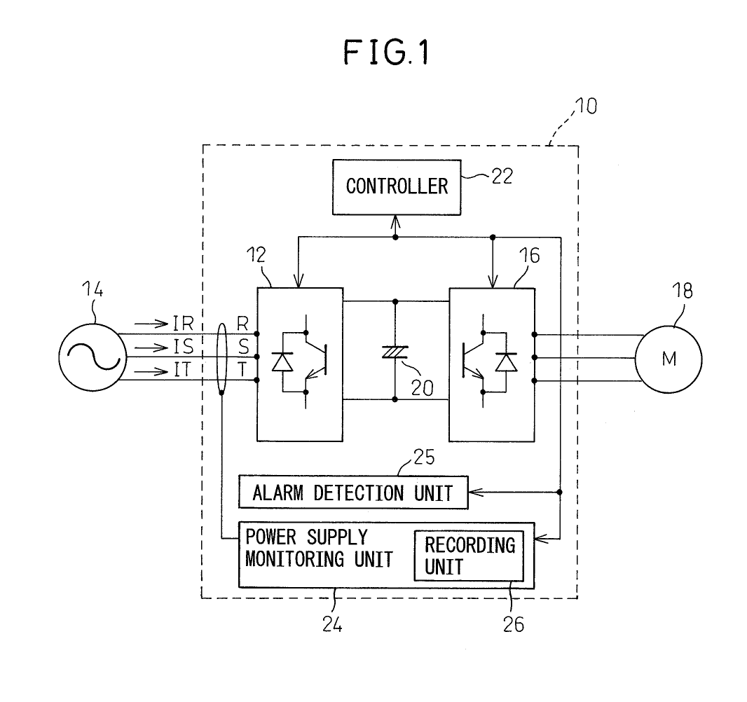

FIG. 1 is a block diagram of a motor driving apparatus 10 according to one embodiment of the present invention. A converter 12 takes three-phase AC power as input from a three-phase AC power supply 14 and converts it into DC power. An inverter 16 converts the DC power output from the converter 12 into frequency variable three-phase AC power for supply to a motor 18. A smoothing capacitor 20 is provided between the converter 12 and the inverter 16. The converter 12 and the inverter 16 are controlled by a controller 22.

A power supply monitoring unit 24 monitors the voltage and current in each phase of the three-phase AC power being supplied to the converter 12 and detects the presence or absence of a fault such as a power interruption, missing phase, voltage imbalance, overvoltage, or overcurrent; if a fault is detected, an alarm signal is sent to the controller 22 which then performs a protection operation such as stopping the operation of the motor. Further, the power supply monitoring unit 24 stores the most recently detected voltage/current values for a predetermined period of time in a register (to be described later). An alarm detection unit 25 detects an alarm condition that may occur in the converter 12, the inverter 16, or the controller 22, and when an alarm condition is detected, the power supply monitoring unit 24 is instructed to save the values currently held in the register to a recording unit 26. The power supply monitoring unit 24 may also save the register values to the recording unit 26 when any one of the earlier mentioned power supply faults is detected.

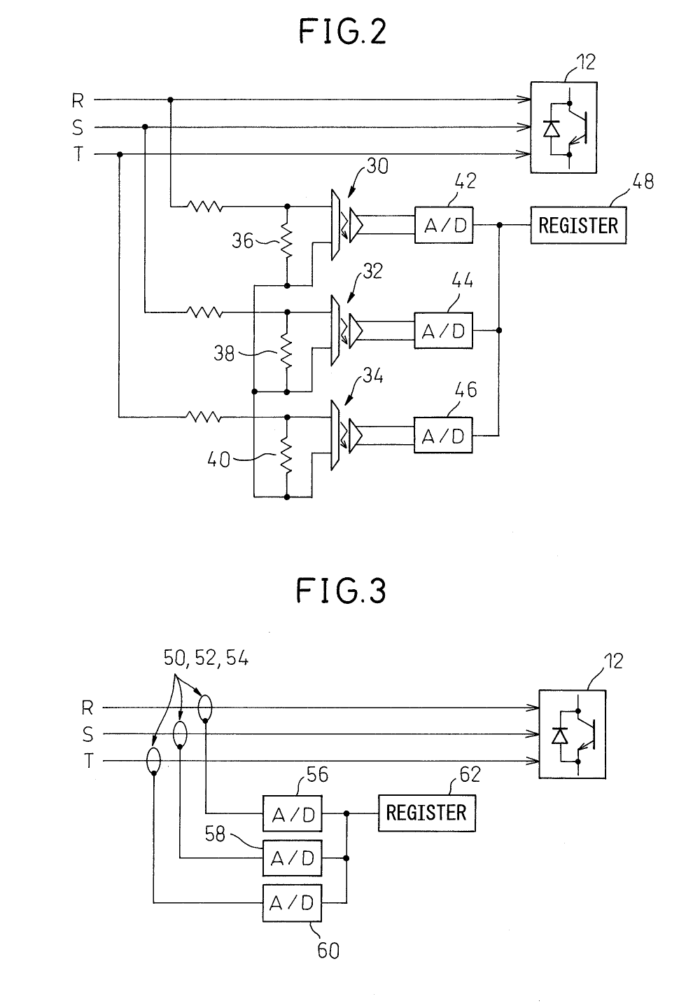

FIG. 2 shows one configuration example of the voltage detecting portion of the power supply monitoring unit 24. Isolation amplifiers 30, 32, and 34 detect the phase voltages relative to the potential at the midpoint of the three-phase AC power formed from resistors 36, 38, and 40. Instead of detecting the phase voltages relative to the potential at the midpoint, phase-to-phase voltages may be detected. A/D converters 42, 44, and 46 periodically sample the phase voltages detected by the respective isolation amplifiers 30, 32, and 34, and convert the sampled values into digital signals for storage in a register 48. The register 48 is, for example, a shift register, and holds the most recent phase voltage data for a predetermined period of time.

FIG. 3 shows one configuration example of the current detecting portion of the power supply monitoring unit 24. Current transformers 50, 52, and 54 detect the phase currents, which are converted by A/D converters 56, 58, and 60 into digital signals for storage in a register 62. The register 62, like the register 48, is for example, a shift register, and holds the most recent phase current data for a predetermined period of time.

Though not shown in FIGS. 2 and 3, the detected voltage and current data are also used to detect power supply faults such as described earlier.

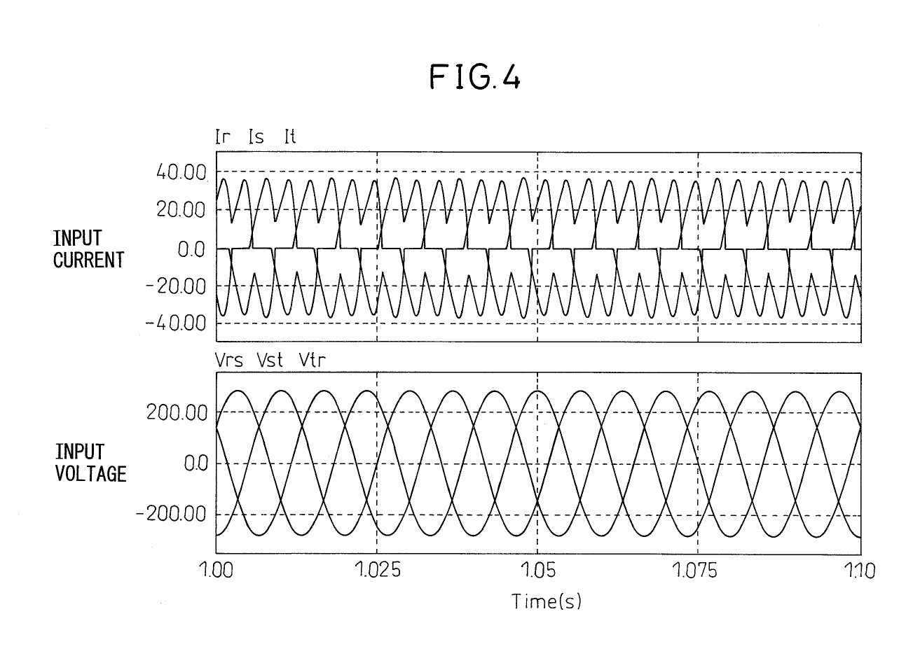

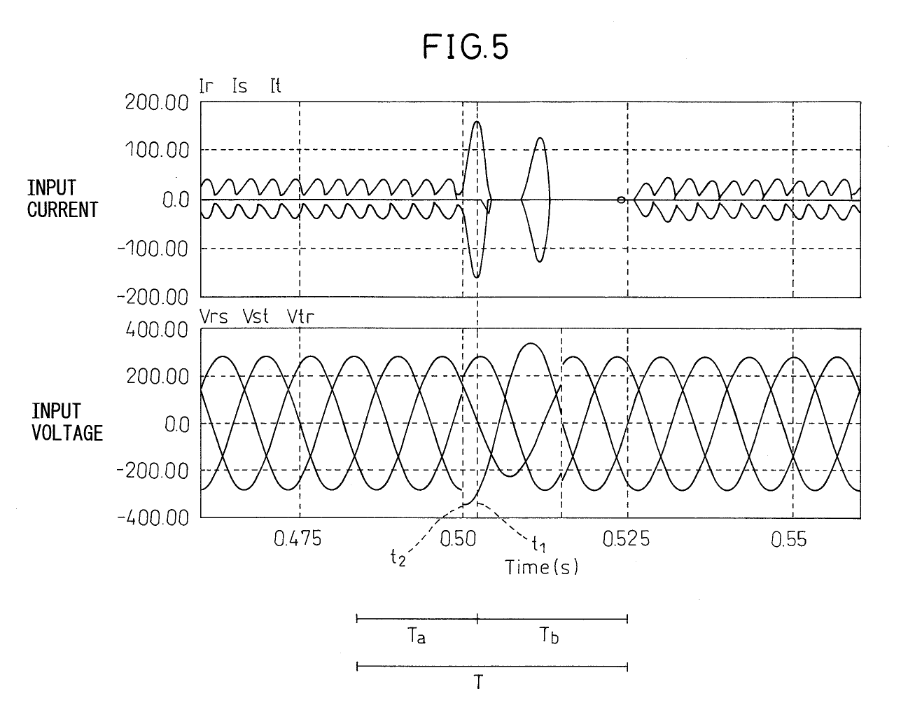

FIG. 4 shows the waveforms of the input current and input voltage during normal operation, and FIG. 5 shows the waveforms of the input current and input voltage when an alarm condition occurs. In FIG. 5, when overcurrent occurs at time t₁, causing an alarm condition in the converter 12, the inverter 16, or the controller 22, the voltage and current data during the interval indicated at “T (=Ta+Tb)” in FIG. 5, i.e., during the period from time t₁-Ta to time t₁+Tb, are recorded in the recording unit 26. Then, when the voltage/current data recorded in the recording unit 26 are displayed on a display (not shown) attached to the motor driving apparatus 10, one can readily see that voltage imbalance occurred in the power supply at time t₂, causing overcurrent and giving rise to an alarm condition.

In addition to saving the data to the recording unit 26 upon detection of an alarm condition in the converter 12, the inverter 16, or the controller 22, the voltage/current data may also be saved to the recording unit 26 in such cases as when the motor output value maintained as an internal parameter in the controller 22 has dropped to a value lower than a motor output command value by more than a predetermined value, when the motor speed has dropped to a value lower than a motor speed command by more than a predetermined value, when abnormality has occurred in other internal data, or when the execution of a control program being executed within the controller 22 has reached a predetermined stage.

Further, provisions may be made to be able to record the data on a removable recording medium in the recording unit 26 and/or transfer the data to some other device so that a person other than the operator can isolate the cause of the fault in the field by referring to the data saved to the recording unit 26.

1. A motor driving apparatus comprising:
a converter converting AC power into DC power;
an inverter converting the DC power output from said converter into frequency variable three-phase AC power for supply to a motor;
a controller controlling said converter and said inverter;
an input power supply detection unit detecting at least one of a current in each phase and voltage in each phase of said AC power;
a power supply monitoring unit storing the most recent data detected by said input power supply detection unit for a predetermined period of time; and
a recording unit which saves said data from said power supply monitoring unit for output at a later time, when a fault has occurred in at least one of said converter, said inverter, and said controller.

2. A motor driving apparatus according to claim 1, wherein said recording unit further saves said data from said power supply monitoring unit for output at a later time, when at least one of the following events has occurred: motor output has dropped to a value lower than a motor output command by more than a predetermined value; motor speed has dropped to a value lower than a motor speed command by more than a predetermined value; abnormality has occurred in the amount of change or the value of other data than said motor output and said motor speed in said controller; and execution of a control program being executed within said controller has reached a predetermined stage.

3. A motor driving apparatus according to claim 1, wherein said data saved for output at a later time is stored on a removable recording medium or transferred externally of said motor driving apparatus so that said data can be output on an apparatus other than said motor driving apparatus.

4. A motor driving apparatus according to claim 2, wherein said data saved for output at a later time is stored on a removable recording medium or transferred externally of said motor driving apparatus so that said data can be output on an apparatus other than said motor driving apparatus.
